(19) United States
(12) Patent Application Publication
(10) Pub. No.: US 2023/0022182 A1
(43) Pub. Date: Jan. 26, 2023

(54) THERMAL MANAGEMENT SYSTEMS HAVING PRESTRESSED BIASING ELEMENTS AND RELATED METHODS

(71) Applicant: The Intel Corporation, Santa Clara, CA (US)

(72) Inventors: Juha Paavola, Hillsboro, OR (US); Justin M. Huttula, 1833 NE 48th Ave, OR (US); Jerrod Peterson, Hillsboro, OR (US); Shawn McEuen, Portland, OR (US); Kerry A. Stevens, Beaverton, OR (US)

(21) Appl. No.: 17/710,822

(22) Filed: Mar. 31, 2022

(51) Int. Cl. G06F 1/20; H05K 7/20

(52) U.S. Cl. CPC G06F 1/206; G06F 1/203; H05K 7/2049

(57) ABSTRACT

Thermal management systems having pre-stressed biasing elements and related methods are disclosed. An example electronic component includes a circuit board, a processor coupled to the circuit board, and a thermally conductive structure positioned adjacent the processor. The thermally conductive structure is to dissipate heat generated by the processor. The electronic component includes a pre-stressed biasing element coupled to the thermally conductive structure and positioned between the processor and the thermally conductive structure. The pre-stressed biasing element is pre-stressed prior to attachment to the thermally conductive structure and the circuit board.

### FIELD OF THE DISCLOSURE

This disclosure relates generally to electronic devices, and, more particularly, to thermal management systems having prestressed biasing elements and related methods.

### BACKGROUND

Electronic devices employ thermal systems to manage thermal conditions to maintain optimal efficiency. To manage thermal conditions, electronic devices employ thermal cooling systems that cool electronic components of the electronic devices during use.

### BRIEF DESCRIPTION OF THE DRAWINGS

FIG. 1 is an example electronic device having an example thermal management system constructed in accordance with teachings of this disclosure.

FIG. 2 is a perspective view of an example electronic component of the example electronic device of FIG. 1 having an example thermal management system disclosed herein.

FIG. 3 is a cross-sectional view of the example electronic component of FIG. 2.

FIG. 4A is a perspective view of an example thermally conductive structure and a pre-stressed biasing element of the example electronic component of FIGS. 2 and 3.

FIG. 4B is a side view of FIG. 4A.

FIG. 5 is a perspective view of the example thermally conductive structure and the pre-stressed biasing element of FIG. 4A shown with an example first clamping tool disclosed herein.

FIG. 6 is a side view of the example pre-stressed biasing element coupled to the example thermally conductive structure via the example first clamping tool of FIG. 5.

FIG. 7 is a bottom perspective view of the example pre-stressed biasing element coupled to the example thermally conductive structure after the example first clamping tool of FIG. 5 is removed from the example pre-stressed biasing element.

FIG. 8 is a cross-sectional side view of the example electronic component of FIGS. 2 and 3 shown in a partially assembled state.

FIG. 9 is a partially exploded view of another example electronic component and a second clamping tool disclosed herein.

FIG. 10 is a perspective view of the example electronic component and the example second clamping tool of FIG. 9.

FIG. 11A is a perspective view of the example electronic component of FIGS. 9 and 10 with the example second clamping tool attached to an example thermally conductive structure of the example electronic component.

FIG. 11B is similar to FIG. 11A but showing the example thermally conductive structure.

FIG. 12 is a flowchart of an example method of manufacturing an example electronic component disclosed herein.

The figures are not to scale. In general, the same reference numbers will be used throughout the drawing(s) and accompanying written description to refer to the same or like parts. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other.

Descriptors “first,” “second,” “third,” etc. are used herein when identifying multiple elements or components which may be referred to separately. Unless otherwise specified or understood based on their context of use, such descriptors are not intended to impute any meaning of priority, physical order, or arrangement in a list, or ordering in time but are merely used as labels for referring to multiple elements or components separately for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for ease of referencing multiple elements or components.

### DETAILED DESCRIPTION

During operation of an electronic device (e.g., a laptop, a tablet, etc.), hardware components such as a processor, graphics card, and/or battery, that are disposed in a body or housing of the device generate heat. To prevent overheating of the hardware components, the electronic device includes a thermal management system to dissipate heat from the electronic device. Example thermal management systems can include active cooling systems or passive cooling systems. Active cooling systems employ forced convection methods to increase a rate of fluid flow, which increases a rate of heat removal. For example, to exhaust heat or hot air generated within the body of the electronic device and cool the electronic device, active cooling systems often employ external devices such as fans or blowers, forced liquid, thermoelectric coolers, etc. Passive cooling systems employ natural convection and heat dissipation by utilizing thermal solutions such as heat sinks and/or heat spreaders to increase (e.g., maximize) radiation and convection heat transfer. For instance, passive cooling systems do not employ external devices such as fans or blowers that would otherwise force airflow to exhaust heat from the housing of the electronic device. Instead, passive cooling systems rely on material characteristic(s) to provide heat transfer pathways between electronic components and outer surfaces or skins of the electronic devices. Passive cooling systems are significantly less expensive than active cooling systems, do not require power to operate, and provide space saving benefits.

Some electronic devices often employ relatively small form factors. For example some electronic devices include housing thicknesses that are between approximately 6.0 millimeters and 6.5 millimeters. Specifically, smaller form factors for electronic devices result in smaller or thinner components (e.g., thinner housing in a stack-up direction, a vertical or z-direction). For example, to achieve overall thickness between 6.0 and 6.5 millimeters or less, some example stack-up dimensions of electronic components between a thermal solution device and a circuit board (e.g., a mother board) need to be between approximately 1.2 millimeters and 1.5 millimeters. To achieve certain form factors, passive cooling systems are employed because such thermal solutions provide space saving benefits. For example, passive cooling systems provide stack-up space saving benefits (e.g., in a vertical or z-direction). To achieve thermal efficiency needed to dissipate heat from an integrated circuit package, thermal solutions are often coupled to an integrated circuit package. For example, thermal solutions for passive cooling systems can include for example, heat pipes, vapor chambers (VC) and heat spreaders that are attached to a die of an integrated circuit package.

To provide sufficient heat transfer between the thermal solutions and the integrated circuit package, a thermal solution device (e.g., a heat pipe, a heat spreader, a vapor chamber, etc.) requires direct contact with the die of the integrated circuit package with a sufficient or target package load (e.g., a compressive force). Specifically, a package load is generated between the thermal solution device and the integrated circuit package to improve thermal or heat transfer performance between the thermal solution and the integrated circuit package. A package load (e.g., a compressive force) between the thermal solution and the integrated circuit package that is too low causes poor thermal performance. For instance, even if a gap between the thermal solution device (e.g., a vapor chamber) and an integrated circuit package is eliminated, thermal performance of the thermal solution device may be less than desired to dissipate heat absent a compressive force between the thermal solution device and the integrated circuit package.

As integrated circuit packages decrease in size and increase in power, the thermal solution devices (e.g., heat sinks and heat spreaders) are larger in area than an area of a chip of the integrated circuit package and/or also have relatively small thicknesses (e.g., have thicknesses of approximately 2.0 and 2.5 millimeters). As a result, thermal solution devices are susceptible to over deflection, causing damage to the thermal solution device. In some examples, to provide package load and/or reduce deflection of the thermal solution device (e.g., a vapor chamber), thermal solution devices (e.g., a vapor chamber) often have relatively stiff characteristics to withstand a package load (e.g., a compressive force). For instance, the thermal solution device is typically coupled to an integrated circuit package via threaded fasteners. A tightening force provided by the threaded fasteners increases a package load (e.g., compressive force) between the thermal solution device and the integrated circuit package. However, a package load that is greater than a desired threshold (e.g., a target package load) can cause risk of damage to the die within the integrated circuit package (e.g., die cracking). For example, over tightening of the screws can impart significant stress (e.g., a force) on the integrated circuit package that can cause (e.g., a die of) the integrated circuit package to crack or become damaged. Thus, thermal solutions employing relatively thick and/or stiff devices increase risk of manufacturing inefficiencies.

In some examples, to reduce damage caused by stiff thermal solution devices and improve manufacturing efficiencies, some example thermal solutions employ biasing elements (e.g., leaf springs). For instance, to improve a thermal solution force on an integrated circuit package and reduce stress imparted to the thermal solution device and/or the integrated circuit package, a biasing element can be employed between the integrated circuit package and the thermal solution device. However, leaf springs are cantilevered and, therefore, are elastic. In some instances, to achieve a target package load for efficient thermal heat transfer between the thermal solution device and the integrated circuit package, some biasing elements require a deflection of approximately 1 millimeter. In other words, to generate a sufficient package load, the biasing elements require significant deflection. However, attachment fasteners that attach a thermal solution device and an integrated circuit package require approximately 1 millimeter of space in the stack-up direction. As a result, to provide sufficient clearance between the integrated circuit package and the thermal solution device to enable deflection of the biasing element and a threading distance provided by the fasteners, integrated circuit packages and thermal solution devices require a dimensional increase in a stack-up direction (e.g., a vertical direction) of approximately 2 millimeters, which is considerably greater than the 1.5 millimeter or less target stack up dimensional value. Thus, as biasing elements reduce risk of damage, such known biasing element systems require a greater amount of space (e.g., a gap between a motherboard and a thermal solution device), which contradicts space requirements for smaller form factor devices. In other words, use of biasing elements increases stack-up distance in the vertical direction, thereby increasing a thickness of a housing of an electronic device.

Example thermal solution devices disclosed herein improve package load, reduce risk of increased stress imparted to an integrated circuit package that can cause damage, and/or reduce deflection of a biasing element, thereby improving manufacturing efficiencies and heat transfer efficiencies, while meeting stack-up requirements for smaller form factor devices. To improve a package load, examples disclosed herein employ pre-stressed biasing elements (e.g., pre-stressed leaf springs). By providing a pre-stressed biasing element, the pre-stressed biasing element decreases spring deflection. Simply increasing a stiffness of a biasing element, without pre-stressing the biasing element, can cause overloading of the integrated circuit package that can lead to damage (e.g., cracking or damage to a die). Additionally, pre-stressed biasing elements disclosed herein prevent die overloading and/or reduce or eliminate die cracking risk. Additionally or alternatively, example biasing elements disclosed herein decrease thermal solution deflection, which reduces stress imparted to the integrated circuit package, thereby decreasing failure risk during manufacturing.

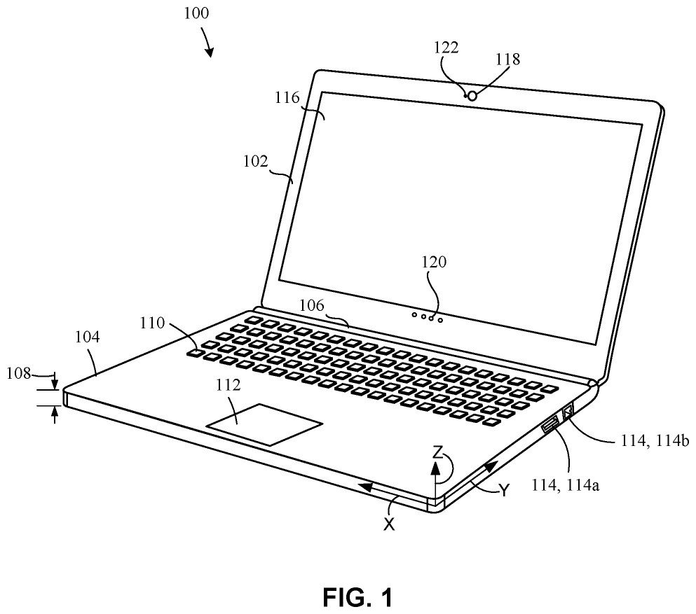

FIG. 1 is an example electronic device 100 constructed in accordance with teachings of this disclosure. The electronic device 100 of the illustrated example is a personal computing device such as, for example, a laptop. The electronic device 100 of the illustrated example includes a first housing 102 coupled to a second housing 104 via a hinge 106. The hinge 106 enables the second housing 104 to rotate or fold relative to first housing 102 between a stored position (e.g., where the second housing 104 is aligned or parallel with the first housing 102) and an open position as shown in FIG. 1 (e.g., where the second housing 104 is non-parallel relative to the first housing 102). In the open position, the second housing 104 can rotate relative to the first housing 102 about the hinge 106 to a desired viewing angle. To provide a relatively small form factor or profile, the second housing 104 of the illustrated example has a thickness 108. For example, the thickness 108 is in a z-direction or stack-up direction (e.g., a vertical direction in the orientation of FIG. 1). For example, the thickness 108 of the second housing 104 can be between 6 millimeters and 6.5 millimeters. In some examples, the thickness 108 can be less than 6.0 millimeters. For example, an overall height of the electronic device 100 when the first housing 102 is in the closed position relative to the second housing 104 can be approximately between 14 millimeters and 20 millimeters. In some examples, the first housing 102 can be detachable relative to the second housing 104. For example, the first housing 102 can be a keyboard or display and the second housing 104 can be a tablet. In some examples, the first housing 102 detaches from the second housing 104 via one or more magnets.

The first housing 102 and/or the second housing 104 houses and/or carries electronic components of the electronic device 100. For example, the electronic components of the illustrated example include a keyboard 110 and a track pad 112, I/O connectors 114 (e.g., universal serial bus (USB) 114a, ethernet connector 114b, etc.), a display 116, a camera 118, a speaker 120 and a microphone 122. Other electronic components can include, but are not limited to, a processor (e.g., a motherboard), a graphics card, a battery, light emitting diodes, memory, a storage drive, an antenna, etc. For example, the first housing 102 houses the display 116, the camera 118, the speakers 120, and the microphone 122. The second housing 104 of the illustrated example houses the keyboard 110 and the track pad 112, which are exposed via the second housing 104 to enable user inputs, the I/O connectors 114, the processor or motherboard, etc.

Although the electronic device 100 of the illustrated example is a laptop, in some examples, the electronic device 100 can be a tablet (e.g., having a single housing), a desktop computer, a mobile device, a cell phone, a smart phone, a hybrid or convertible PC, a personal computing (PC) device, a sever, a modular compute device, a digital picture frame, a graphic calculator, a smart watch, and/or any other electronic device that employs passive cooling.

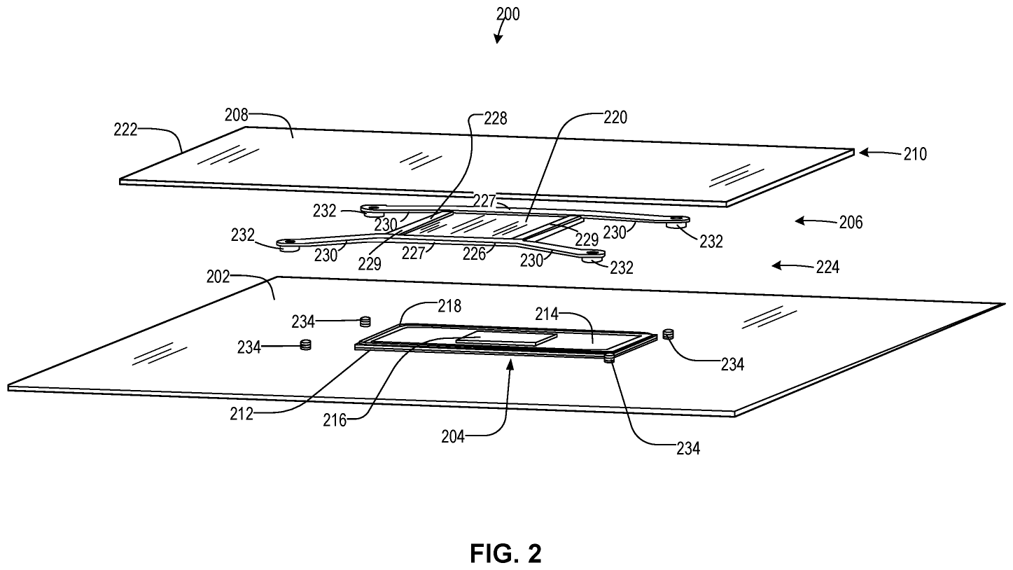

FIG. 2 is an exploded view of an example electronic component 200 in accordance with teachings of this disclosure. The second housing 104 (FIG. 1) of the illustrated example carries the electronic component 200. In some examples, an auxiliary or secondary hardware component assembly can be located and/or carried by the first housing 102 (FIG. 1). In some examples, when the electronic component 200 is a detachable device or tablet, the electronic component 200 is the first housing 102.

The electronic component 200 of the illustrated example includes a circuit board 202 (e.g., a printed circuit board (PCB), a mother board, etc.), a processor 204 (e.g., a system on chip (SOS), a central processing unit package), a load mechanism 206, and a thermally conductive structure 208 (e.g., a heat spreader) of a passive thermal management system 210. The circuit board 202 supports one or more circuit components (e.g., resistors, transistors, capacitors, diodes, inductors, integrated circuits, etc.). The processor 204 can include any type of processing or electronic circuitry, such as a central processing unit (CPU), graphics processing unit (GPU), microprocessor, microcontroller, accelerator, field-programmable gate array (FPGA), etc. In some examples, the processor 204 is a central processing unit (CPU) that does not exceed 10 watts of power. However, in some examples, the processor 204 can exceed 10 watts of power. The processor 204 of the illustrated example is coupled to the circuit board 202 via a socket interface 212. The socket interface 212 can include component(s) or mechanism(s) designed to couple (e.g., mechanically and/or electrically) the processor 204 (e.g., a processor die) and the circuit board 202. The processor 204 of the illustrated example is an integrated circuit (IC) chip or package that includes a central processing unit package 214, a die 216, and a package stiffener 218. In the illustrated example, a pedestal 220 thermally couples the die 216 and the thermally conductive structure 208.

The thermally conductive structure 208 of the illustrated example is a vapor chamber 222 (e.g., a copper structure or plate). However, in some examples, the thermally conductive structure 208 can be a heat pipe, a heat spreader, and/or any other heat spreader or structure to dissipate heat away from the processor 204. In some examples, the vapor chamber 218 can be a heat sink that includes a metal enclosure that is vacuum sealed and includes an internal wick structure attached to the inside walls of the enclosure that moves liquid around the vapor chamber 222 using capillary action to spread heat along a surface area (e.g., upper surface and a lower surface) of the vapor chamber 222. In some examples, the vapor chamber is a planar heat pipe, which can spread heat in two dimensions (e.g., across a surface area of the vapor chamber). The vapor chamber 222 of the illustrated example can be composed of brass, copper and/or any other suitable material(s) for transferring and/or spreading heat.

The load mechanism 206 of the illustrated example is a biasing element. In particular, the biasing element is a pre-stressed leaf spring 224. The pre-stressed leaf spring 224 of the illustrated example includes a frame 226 to support or couple to the pedestal 220. The frame 226 of the illustrated example has a rectangular or square shape and has an opening 228 (e.g., a center cutout) to enable the pedestal 220 to contact (e.g., directly contact) the die 216 and the vapor chamber 222. For example, the frame 226 of the illustrated example has longitudinal walls 227 (e.g., two walls in the x-direction) interconnected by lateral walls 229 (e.g., two walls in the y-direction) extending between the respective ones of the longitudinal walls 227. The opening 228 is formed by the longitudinal walls 227 and the lateral walls 229.

Additionally, the pre-stressed leaf spring 224 of the illustrated example includes a plurality of arms 230 extending from the frame 226. For example, the arms 230 of the illustrated example are cantilevered from the frame 226. Each of the arms 230 of the pre-stressed leaf spring 224 of the illustrated example includes a threaded boss 232 to receive respective ones of fasteners 234 (e.g., thermal mechanism attachment screws). In the illustrated example, the pre-stressed leaf spring 224 includes four arms. However, in some examples, the pre-stressed leaf spring 224 can include five arms, six arms, and/or any number of arms. Additionally, in some examples, the load mechanism 206 can include a plurality of biasing elements (e.g., leaf springs). In some examples, the plurality of leaf springs are not attached or coupled to the frame 226 (e.g., a common frame) and/or to the pedestal 220 as shown in FIG. 2. The pre-stressed leaf spring 224 of the illustrated example can be made of steel or any other material.

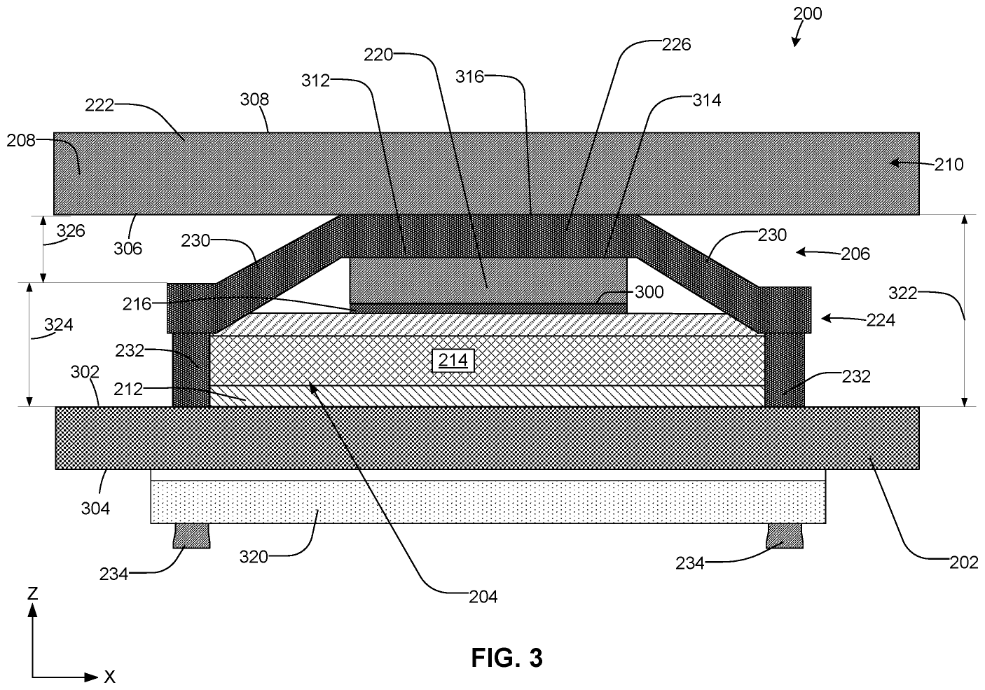

FIG. 3 is a side, cross-sectional view of the example electronic component 200 of FIG. 2. The processor 204 of the illustrated example is positioned between the circuit board 202 and the thermally conductive structure 208. Specifically, the processor 204 is positioned between a first surface 302 (e.g., a first horizontal or flat surface) of the circuit board 202 opposite a second surface 304 (e.g., a second horizontal or flat surface) and a first surface 306 (e.g., a first horizontal or flat surface) of the thermally conductive structure 208 opposite a second surface 308 (e.g., a second horizontal or flat surface) of the thermally conductive structure 208. The first surface 302 of the circuit board 202 of the illustrated example is oriented toward (e.g., faces) the first surface 306 of the thermally conductive structure 208. In other words, the processor 204 of the illustrated example is sandwiched between the first surface 302 of the circuit board and the first surface 306 of the thermally conductive structure 208. The socket interface 212 couples the processor 204 and the circuit board 202.

The pedestal 220 of the illustrated example is positioned (e.g., sandwiched) between the processor 204 and the thermally conductive structure 208. For example, a first side 310 (e.g., a first surface) of the pedestal 220 engages (e.g., directly engages) the processor 204 (e.g., the die 216 of the processor 204) and a second side 312 of the pedestal 220 opposite the first side 310 engages (e.g., directly engages) the first surface 306 of the thermally conductive structure 208. In some examples, a thermal compound layer (e.g., a thermal paste, etc.) can be positioned between the processor 204 and the pedestal 220 to improve or increase heat transfer efficiency.

Additionally, the load mechanism 206 of the illustrated example is positioned (e.g., sandwiched) between the pedestal 220 and the thermally conductive structure 208. For example, a first side 314 (e.g., a first surface) of the frame 226 of the pre-stressed leaf spring 224 is coupled to the second surface 312 of the pedestal 220 and a second side 316 (e.g., a second surface) of the frame 226 opposite the first side 314 is coupled to the first surface 306 of the thermally conductive structure 208. As described in greater detail below, the load mechanism 206 is coupled to the thermally conductive structure 208 via welding, solder, etc.

To provide a package load (e.g., a compressive force) between the thermally conductive structure 208 and the processor 204, the load mechanism 206 of the illustrated example is coupled to the printed circuit board 202 via the fasteners 234. Specifically, a backing plate 320 is positioned on the second surface 304 of the circuit board 202 to support the printed circuit board 202. Respective ones of the fasteners 234 are received by respective ones of the threaded bosses 232 of the pre-stressed leaf spring 224 via openings formed in the backing plate 320 and the printed circuit board 202. Thus, the loading mechanism 206 of the illustrated example imparts a package load (e.g., a compressive force) to cause the thermally conductive structure 208 to engage the die 216 via the pedestal 220 with a compressive force sufficient to improve thermal conductivity efficiency of the passive thermal management system 210. Specifically, the fasteners 234 cause the arms 230 of the pre-stressed leaf spring 224 to deflect (e.g., toward the circuit board 202 in the z-direction) and generate a compressive force against the processor 204. The fasteners 234 impart a clamping force between the backing plate 320 and the threaded bosses 232 to cause the arms 230 of the pre-stressed leaf spring 224 to deflect.

The pre-stressed leaf spring 224 deflects within a space or a thickness gap 322 formed between (e.g., the first surface 302 of) the circuit board 202 and (e.g., the first surface 306 of) the thermally conductive structure 208. The thickness gap 322 is often determined by a thread distance 324 (e.g., in z-direction) of the fasteners 234 needed to couple to the loading mechanism 206 (e.g., a package load mechanism) and a required deflection 326 of the load mechanism 206 needed to impart a target package load for thermal conductivity efficiencies. The thickness gap 322 of the illustrated example is between approximately 1.3 millimeters and 1.5 millimeters. The thickness gap 330 provides a role in determining the thickness 108 of the second housing 104 of FIG. 1. In some examples, the pre-stressed leaf spring 224 of the illustrated example enables the thickness gap 322 of approximately 1.5 millimeter, generates a bending stress on the vapor chamber 222 of approximately 87 megapascals (MPa), and causes the vapor chamber 222 to deflect approximately 0.70 millimeters (e.g., in the z-direction). In comparison, a traditional leaf spring that is not pre-stressed requires a gap height of approximately 2 millimeters, generates a bending stress on the vapor chamber of approximately 112 megapascals (MPa), and causes the vapor chamber to deflect approximately 1.26 millimeters (e.g., in the z-direction). Thus, in some examples, the example pre-stressed leaf spring 224 disclosed herein can provide at least a 25 percent reduction in the gap thickness, a 22 percent reduction in vapor chamber bending stress, and a 56 percent reduction in the vapor chamber deflection. Therefore, by employing the pre-stressed leaf spring 224, the thickness gap 322 can be reduced because a smaller amount of deflection 326 of the pre-stressed leaf spring 224 (e.g., in the z-direction) is needed to generate a target packing load compared to a non-prestressed leaf spring. In some instances, to achieve a target package load for efficient thermal heat transfer between the thermally conductive structure 208 and the processor 204, the pre-stressed leaf spring 224 can generate sufficient package load with a 0.3 millimeter to 0.5 millimeter deflection, as opposed to non-prestressed leaf springs that require approximately 1 millimeter deflection to generate at least the same amount of package load. Thus, as noted above, the pre-stressed leaf springs enables the thickness gap 322 to be approximately 1.3 millimeters and 1.5 millimeters, without affecting thermal efficiency compared to a non-prestressed leaf spring.

In operation, the thermally conductive structure 208 provides a passive cooling system or heat sink for the electronic device 100. For example, heat generated by components of the circuit board 202 and/or the processor 204 of the illustrated example is dissipated (e.g., spread) across the first surface 306 of the thermally conductive structure 208. For example, heat generated by the processor 204 is spread and/or absorbed across the thermally conductive structure 208 (e.g., the vapor chamber 222) and transferred to the second surface 308 of the thermally conductive structure 208. The thermally conductive structure 208 is structured to dissipate and/or transfer away the heat from the second surface 308 to a frame of the second housing 104. For example, the second surface 308 of the thermally conductive structure 208 can be configured to transfer heat to a skin or frame (e.g., a chassis) of the second housing 104.

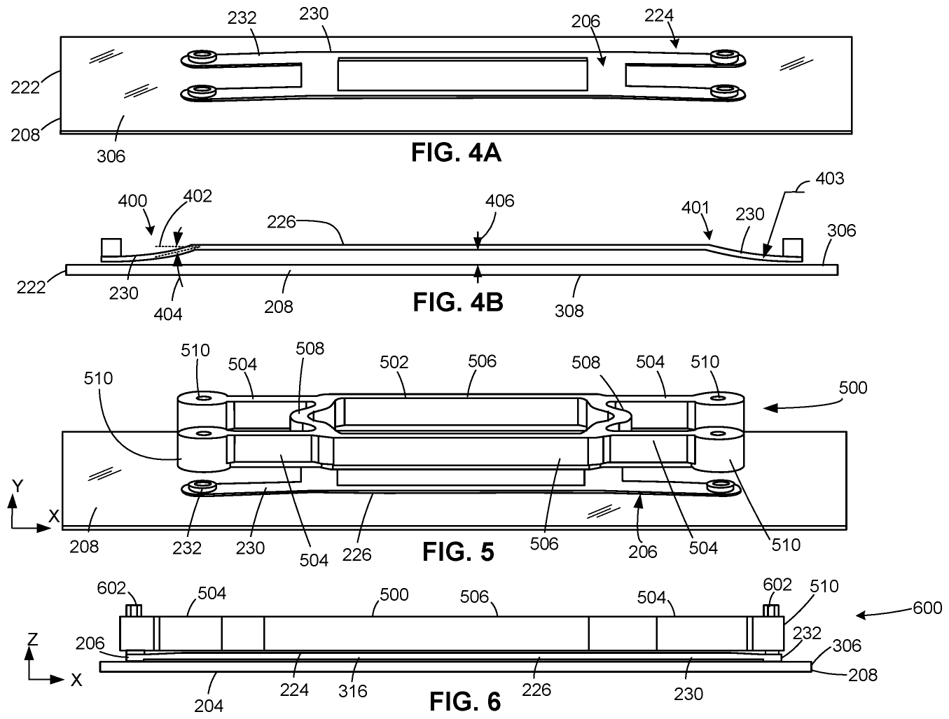

FIGS. 4A and 4B illustrate the load mechanism 206 and the thermally conductive structure 208 of FIGS. 2 and 3 prior to assembly to the electronic component 200. FIG. 4A is a bottom, perspective view of example the load mechanism 206 decoupled or detached from the thermally conductive structure 208. FIG. 4B is a side view of the example the load mechanism 206 and the thermally conductive structure 208 of FIG. 4A. Referring to FIGS. 4A and 4B, the pre-stressed leaf spring 224 is pre-stressed (e.g., at the factory) prior to assembly with the thermally conductive structure 208 and/or the electronic component 200. In other words, the pre-stressed leaf spring 224 is pre-stressed prior to attachment to the thermally conductive structure 208 (e.g., the vapor chamber 222). As shown in FIGS. 4A and 4B, the vapor chamber 222 is substantially flat (e.g., it is perfectly flat (e.g., zero degrees of deflection relative to horizontal 402) or has a curvature of approximately 0.5 to 1 degree relative to horizontal 402). In contrast, in an initial position 400 (e.g., a manufactured position), the arms 230 of the pre-stressed leaf spring 224 are bent or angled relative to the frame 226 and/or horizontal 402. In other words, each of the arms 230 (e.g., a leaf) of the pre-stressed leaf spring 224 has a radius of curvature 403 (e.g., prior to coupling or attachment to the thermally conductive structure 208 or the vapor chamber 222).

In the illustrated example, the first surface 306 of the thermally conductive structure 208 is oriented toward the second side 316 of the pre-stressed leaf spring 224 when the pre-stressed leaf spring 224 is oriented relative to the thermally conductive structure 208. Additionally, the arms 230 of the pre-stressed leaf spring 224 are angled or tapered (e.g., bent) from the frame 226 and towards the first surface 306 of the thermally conductive structure 208 at an angle 404 from horizontal 402 in the initial position 400 (e.g., a non-stressed or non-deflected position). As a result, a gap 406 forms between the first surface 306 of the thermally conductive structure 208 and the frame 226 of the pre-stressed leaf spring 224 when the pre-stressed leaf spring 224 is positioned on the first surface 306 of the thermally conductive structure 208. As used herein, “pre-stressed biasing element” or “pre-stressed leaf spring” means that the biasing element or leaf spring is formed or manufactured (e.g., at the factory) with a deflection such that the leaf spring is not substantially flat. In other words, such deflection is formed in the pre-stressed biasing element or the pre-stressed leaf spring prior to attachment to the thermally conductive structure 208, the vapor chamber 222, and/or the electronic component 200. As used herein, “substantially flat” means perfectly flat relative to horizontal or within five degrees from horizontal (e.g., a slight bend).

FIG. 5 is a bottom, perspective view of an example first clamping tool 500 to facilitate assembly of the thermally conductive structure 208 and the load mechanism 206 (e.g., the pre-stressed leaf spring 224). Referring to FIG. 5, the first clamping tool 500 of the illustrated example has a shape and/or profile that is complimentary to the shape of a non-prestressed leaf spring. For example, the first clamping tool 500 of the illustrated example includes a frame 502 and arms 504 protruding or projecting from the frame 502. The frame 502 of the illustrated example has a rectangular or square shaped profile. Specifically, the frame 502 is complimentary to the frame 226 of the pre-stressed leaf spring 224. The frame 502 includes longitudinal walls 506 (e.g., two walls in the x-direction) and lateral walls 508 (e.g., two walls in the y-direction) coupling the longitudinal walls 506. In other words, the frame 502 aligns with the frame 226 of the pre-stressed leaf spring 224 such that the longitudinal walls 506 align (e.g., vertically or substantially parallel) relative to the longitudinal walls 227 (FIG. 2) of the frame 226, respectively, and the lateral walls 508 align (e.g., vertically or substantially parallel) relative to the lateral walls 229 (FIG. 2) of the frame 226. The arms 504 of the illustrated example each project in a direction away from the frame 502. In other words, respective ones of the arms 504 align (e.g., vertically or above) with respective ones of the arms 230 of the pre-stressed leaf spring 224. However, in contrast to the arms 230 of the pre-stressed leaf spring 224, the arms 504 of the first clamping tool 500 have a relatively straight profile (e.g., do not have an angle) relative to the frame 502 or horizontal 402 (FIG. 4B). Additionally, each of the arms 504 of the first clamping tool 500 of the illustrated example includes a threaded boss 510. In the illustrated example, the first clamping tool 500 has four arms complementary to the arms 230 of the pre-stressed leaf spring 224. Respective ones of the threaded bosses 510 align with respective ones of the threaded bosses 232 of the pre-stressed leaf spring 224.

FIG. 6 is a side view of the thermally conductive structure 208 and the load mechanism 206 shown in an example assembled state 600. Specifically, the first clamping tool 500 is coupled to the pre-stressed leaf spring 224 to remove the gap 406 (FIG. 4) between the frame 226 and the thermally conductive structure 208 to facilitate attachment of the thermally conductive structure 208 and the pre-stressed leaf spring 224 via, for example, welding or soldering. In the illustrated example, the first clamping tool 500 is coupled to the pre-stressed leaf spring 224. Specifically, the first clamping tool 500 is coupled to the pre-stressed leaf spring 224 via fasteners 602 (threaded screws) coupled to the threaded bosses 232 of the pre-stressed leaf spring 224 and the threaded bosses 510 of the first clamping tool 500. As the fasteners 602 are tightened, the first clamping tool 500 exerts a pressure or force toward the pre-stressed leaf spring 224. As a result, the first clamping tool 500 causes the arms 230 of the pre-stressed leaf spring 224 to deflect such that the angle 404 between the frame 226 and the arms 230 is reduced or eliminated (e.g., zero or within 5 degrees of horizontal 402). In other words, the first clamping tool 500 causes the pre-stressed leaf spring 224 to be substantially flat such that the arms 230 are substantially flat relative to the frame 226 (e.g., the angle 404 is reduced to zero degrees or within 5 degrees relative to horizontal 402). When the pre-stressed leaf spring 224 is deflected via the first clamping tool 500, the pre-stressed leaf spring 224 is attached to the thermally conductive structure 208. For example, the frame 226 (e.g., the second side 316) is soldered to the first surface 306 of the thermally conductive structure 208. In other words, although the pre-stressed leaf spring 224 is pre-stressed and/or the arms 230 are bent relative to the frame 226 (e.g., in a non-flexed or initial position), the pre-stressed leaf spring 224 is compressed to flat state (e.g., the arms 230 are substantially parallel relative to horizontal 402) when the pre-stressed leaf spring 224 is attached or coupled to the thermally conductive structure 208. Additionally, the pedestal 220 can be attached to the frame 226 of the pre-stressed leaf spring 224 when the pre-stressed leaf spring 224 is in the assembled state 600 of FIG. 6 (e.g., when the first clamping tool 500) is attached to the pre-stressed leaf spring 224. In some examples, the pedestal 220 can be attached to the pre-stressed leaf spring 224 and/or the thermally conductive structure 208 after removal of the first clamping tool 500.

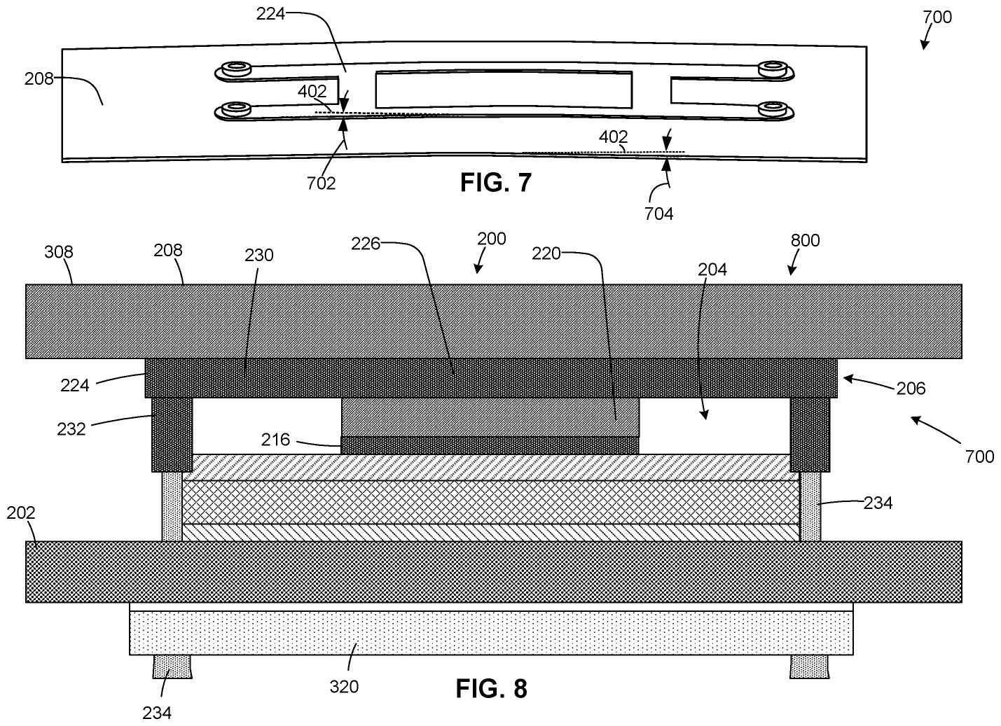

FIG. 7 is a bottom, perspective view of the thermally conductive structure 208 and the load mechanism 206 in an assembled state 700. When the pre-stressed leaf spring 224 is coupled to the thermally conductive structure 208, the pre-stressed leaf spring 224 exerts a load on the thermally conductive structure 208. For instance, when the first clamping tool 500 is detached from the pre-stressed leaf spring 224 after the pre-stressed leaf spring 224 is attached (e.g., permanently attached or welded) to the thermally conductive structure 208 (FIG. 6), the arms 230 of the pre-stressed leaf spring 224 deflect toward the initial position 400 (FIG. 4) to a partially deflected position 702. The partially deflected position 702 has an angle 704 relative to horizontal 402. The angle 704 is less than the angle 404 of the initial position 400 of FIG. 4. As a result, the pre-stressed leaf spring 224 causes the thermally conductive structure 208 to deflect relative to horizontal 402. For example, the thermally conductive structure 208 deflects at an angle 704 relative to horizontal 402 due to the force of the pre-stressed leaf spring 224. The angle 704 of the illustrated example is approximately between one degree and five degrees relative to horizontal 402. For example, in the preassembled state 700, a bend stress imparted to the thermally conductive structure 208 is approximately 29 megapascals (MPa) and a deflection of the thermally conductive structure 208 is approximately 0.90 millimeters.

FIG. 8 is a cross-sectional side view of the example electronic component 200 of FIG. 2 in a partially assembled state 800. Specifically, the thermally conductive structure 208 and the loading mechanism 206 is shown in the assembled state 700 but detached from the processor 204 and the circuit board 202. In the assembled state 700, the thermally conductive structure 208 and the loading mechanism 206 is oriented such that the pre-stressed leaf spring 224 is oriented toward the circuit board 202. The fasteners 234 are passed through the backing plate 320 and the circuit board 202 and fastened to respective ones of the threaded bosses 232 of the pre-stressed leaf spring 224. When the fasteners 234 are tightened, the fasteners 234 cause (e.g., draw) the arms 230 of the pre-stressed leaf spring 224 to deflect (e.g., bend) away from the frame 226 and toward the circuit board 202 (e.g., as shown in FIG. 3). In this manner, the pre-stressed leaf spring 224 causes the thermally conductive structure 208 to engage the pedestal 220 and/or the die 216 (e.g., via the pedestal 220) with a package load (e.g., a compressive force) to improve heat transfer efficiency of the passive thermal management system 210. In some examples, to provide additional support to the thermally conductive structure 208 during assembly, a second clamping tool can be provided to the second surface 308 of the thermally conductive structure 208.

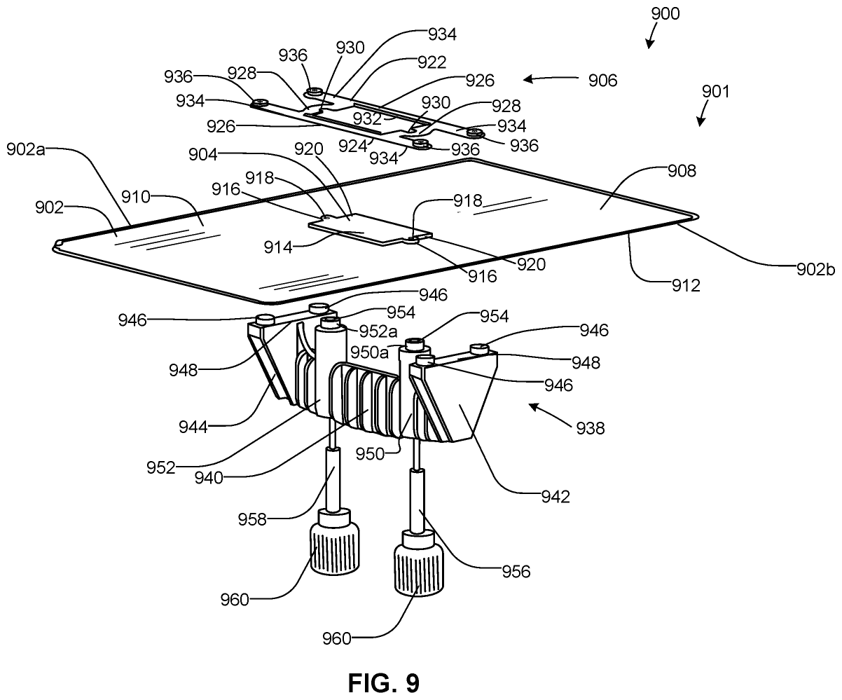

FIG. 9 is a partially exploded view of another example electronic component 900 disclosed herein. The electronic component 900 of the illustrated example is shown in a partially assembled state 901. The electronic component 900 of the illustrated example includes a thermally conductive structure 902, a pedestal 904 and a loading mechanism 906. The thermally conductive structure 902, the pedestal 904 and the loading mechanism 906 can couple to the processor 204, the circuit board 202 and the backing plate 320 of the example electronic component 200 of FIGS. 2-8 in place of the thermally conductive structure 208, the pedestal 220, and the loading mechanism 206 of FIGS. 2-8. The thermally conductive structure 902, the pedestal 904 and the loading mechanism 906 function substantially similar to the thermally conductive structure 208, the pedestal 220, and the loading mechanism 206 of FIGS. 2-8. The thermally conductive structure 902 of the illustrated example is vapor chamber 908. For example, the vapor chamber 908 can be made of copper, aluminum, titanium and/or any other thermally conductive material(s). In some examples, the thermally conductive structure 902 can be a heat spreader, a heat pipe, a plate, and/or any other heat spreader. The pedestal 220 of the illustrated example is a plate composed of a thermally conductive material(s) to enhance or improve heat transfer between a processor (e.g., the die 216 of the processor 204 of FIGS. 2-8) and the thermally conductive structure 902.

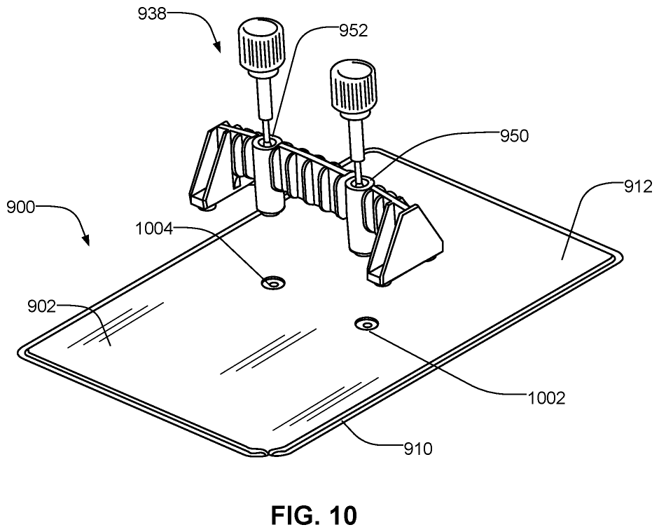

The pedestal 904 of the illustrated example is coupled (e.g., attached or soldered) to a first surface 910 of the thermally conductive structure 902 opposite a second surface 912. The pedestal 904 includes a plate 914 and flanges 916 with bores 918 (e.g., threaded bores) extending from respective edges 920 of the plate 914. As shown in FIG. 10 below, the bores 918 align with apertures of the thermally conductive structure 902.

The loading mechanism 906 of the illustrated example is a pre-stressed leaf spring 922. Similar to the pre-stressed leaf spring 224 of FIGS. 2-8, the pre-stressed leaf spring 922 of the illustrated example includes a frame 924 that includes front and rear longitudinal frame members 926 and lateral frame members 928 extending between the longitudinal frame members 926 and interconnecting the longitudinal frame members 926. The lateral frame members 928 of the illustrated example includes cutouts 930 that align with respective ones of the bores 918 of the pedestal 904. Additionally, the frame 924 defines an opening 932 (e.g., a cutout) that aligns with and/or receives the pedestal 904. Additionally, the pre-stressed leaf spring 922 of the illustrated example includes a plurality of arms 934 extending from the frame 924. For example, the arms 934 of the illustrated example are cantilevered from the frame 924. Each of the arms 934 of the pre-stressed leaf spring 922 of the illustrated example includes a threaded boss 936 to receive respective ones of thermal mechanism attachment fasteners (e.g., the fasteners 234 of FIGS. 2-8). In the illustrated example, the pre-stressed leaf spring 922 includes four arms. However, in some examples, the pre-stressed leaf spring 922 can include one arm, four arms, five arms, six arms, and/or any number of arms. Additionally, in some examples, the load mechanism 906 can include a plurality of biasing elements (e.g., leaf springs, springs and/or other springs). In some examples, the plurality of leaf springs are not attached or coupled to a frame 924 (e.g., a common frame) and/or to the pedestal 904.

In the illustrated example, although the pre-stressed leaf spring 922 is shown detached or in an exploded view relative to the thermally conductive structure 902, the thermally conductive structure 902 is attached with the pre-stressed leaf spring 922. For example, the thermally conductive structure 902 and the pre-stressed leaf spring 922 can be attached together (e.g., via soldering) similar to the thermally conductive structure 208 and the pre-stressed leaf spring 224 of FIGS. 2-8. For instance, the first clamping tool 500 as shown in FIGS. 5 and 6 can be employed to couple the thermally conductive structure 902 and the pre-stressed leaf spring 922.

A second clamping tool 938 of the illustrated example is employed to facilitate attachment of a processor and a circuit board after the loading mechanism 906 is attached to the thermally conductive structure 902. In other words, the second clamping tool 938 is employed to support the thermally conductive structure 902 when the circuit board 202 is coupled to the pre-stressed leaf spring 922 via attachment fasteners (e.g., the fasteners 234 of FIGS. 2-8). For example, the second clamping tool 938 prevents damage and/or restricts or prevents deflection (e.g., bending and/or twisting) of the thermally conductive structure 902 during assembly of the thermally conductive structure 902 and the circuit board 202. In other words, the second clamping tool 938 can be used after attachment of the pre-stressed leaf spring 922 with the thermally conductive structure 902 (e.g., via the first clamping tool 500 as shown in FIGS. 5 and 6) and when fastening the thermally conductive structure and the pre-stressed leaf spring assembly with the circuit board 202 via the fasteners 234 (e.g., as shown in FIGS. 1-8).

The second clamping tool 938 of the illustrated example includes an elongated body 940 that spans between a first lateral edge 902a and a second lateral edge 902b of the thermally conductive structure 902. The body 940 includes a first pillar 942 and a second pillar 944 opposite the first pillar 942. Each of the pillars 942, 944 includes raised bosses or protrusions 946 (e.g., cylindrically shaped protrusions) extending from a lower surface 948 of the respective pillars 942, 944. Specifically, each of the pillars 942, 944 includes two protrusions 946 (e.g., two raised bosses) and are structured to align (e.g., vertically align in the z-direction) with respective ones of the threaded bosses 936 of the pre-stressed leaf spring 922. Thus, the number of protrusions 946 of the illustrated example matches the number of threaded bosses 936. Additionally, the body 940 defines a first cylinder 950 and a second cylinder 952 positioned between the first pillar 942 and the second pillar 944. Respective ends of the cylinders 950, 952 extend past or beyond the lower surface 948 of the pillars 942, 944. Additionally, the respective ends of the cylinders 950, 952 include a stepped profile such that a first portion of the cylinders 950, 952 have a first diameter and a second portion (e.g., the tips) of the cylinders 950, 952 have a second diameter smaller than the first diameter. The first pillar 942 is spaced apart from the second cylinder 952. Each of the first cylinder 950 and the second cylinder 952 defines an opening 954 (e.g., a through hole). To couple the second clamping tool 938 to the thermally conductive structure 902, the second clamping tool 938 of the illustrated example includes a first fastener 956 and a second fastener 958. The first fastener 956 is received by the opening 954 of the first cylinder 950 and the second fastener 958 is received by the opening 954 of the second cylinder 952. The first and second fasteners 956, 958 each include a knob 960 (e.g., a handle) to facilitate or enable a user to rotate of the respective fasteners 956, 958 relative to the first cylinder 950 and the second cylinder 952 without use of a tool (e.g. a wrench, a screwdriver, etc.).

FIG. 10 is a perspective view of the electronic component 900 of FIG. 9 and the second clamping tool 938 removed from the electronic component 900. In the illustrated example, the second surface of thermally conductive structure 902 includes a first aperture 1002 and a second aperture 1004. The apertures 1002, 1004 extend through the first surface 910 and the second surface 912 of the thermally conductive structure 902. The apertures 1002, 1004 have a countersink to receive the respective ends 950a, 952a of the first cylinder 950 and the second cylinder 952, respectively. The apertures 1002,1004 can be formed via a secondary process (e.g. a drilling process) after formation of the thermally conductive structure 902.

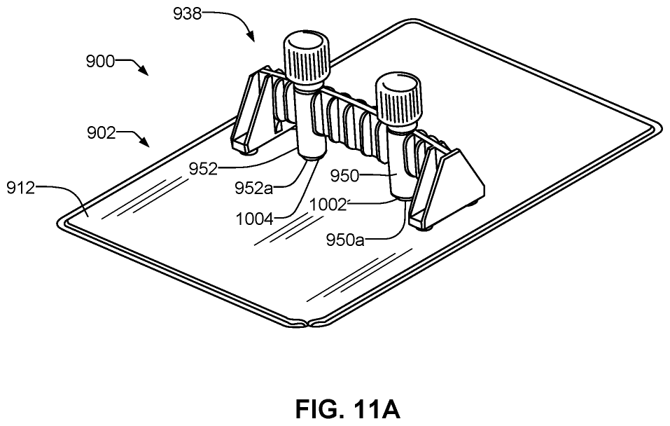

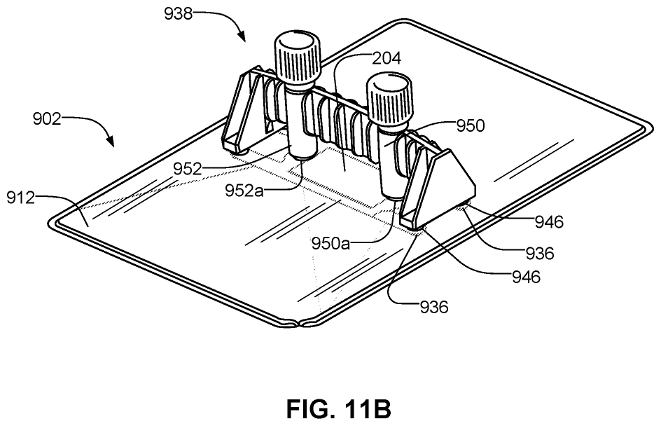

FIG. 11A is a perspective view of the electronic component 900 of FIGS. 9 and 11 with the second clamping tool 938 coupled to the thermally conductive structure 902. FIG. 11B is a perspective view of the electronic component 900 of FIG. 11A but the thermally conductive structure 902 (e.g., the vapor chamber 924) is shown in a transparent view to show the pedestal 904 and the pre-stressed leaf spring 922 in relation to the second clamping tool 938. Referring to FIGS. 11A and 11B, the second clamping tool 938 is fastened to the thermally conductive structure 902 via the fasteners 956, 958. For example, when coupled to the second surface 912 of the thermally conductive structure 902, the ends of the cylinders 950, 952 engage (e.g., are flush mounted) with the second surface 912, and the ends 950a, 952a (e.g., tips) of the cylinders 950, 952 protrude within the respective countersinks of the apertures 1002, 1004. The raised protrusions 946 engage the second surface 912 of the thermally conductive structure 902. Specifically, the raised protrusions 946 do not extend through the thermally conductive structure 902. To couple the second clamping tool 938 to the thermally conductive structure 902, the fasteners 956, 958 are rotated in a first rotational direction (e.g., a counterclockwise direction in the orientation of FIG. 11A) via the knobs 960 to threadably couple the fasteners 956, 958 and the pedestal 904 (FIG. 9). To remove the second clamping tool 938 after the thermally conductive structure 902 is coupled to a circuit board (e.g., the circuit board 202 of FIGS. 1-8), the fasteners 956, 958 are rotated in a second rotational direction (e.g., a clockwise direction in the orientation of FIG. 11A) via the knobs 960 to threadably decouple the fasteners 956, 958 and the pedestal 904 (FIG. 9). In some examples, after the second clamping tool 938 is removed, a filler material (e.g., an epoxy, copper tape, copper button, etc.) can be inserted in the apertures 1002, 1004.

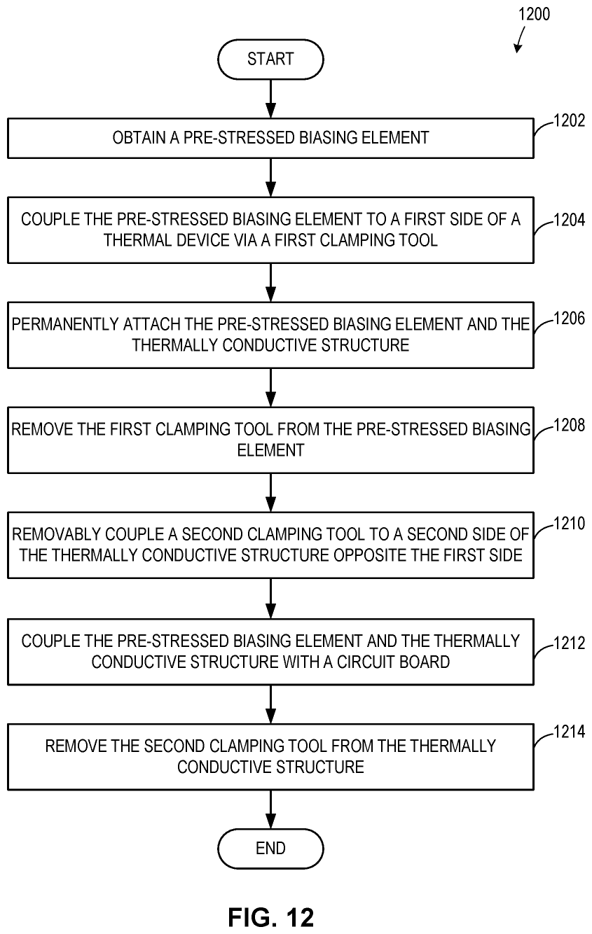

FIG. 12 is a flowchart of an example method 1200 of manufacturing an example electronic component disclosed herein. For example, the method 1200 of FIG. 12 may be used to fabricate or form the example electronic component 200 of FIGS. 1-8 and/or the example electronic component 900 of FIGS. 9, 10, 11A, and 11B. To facilitate discussion of the example method 1200, the example method 1200 is described in connection with the example electronic component 200 and the electronic component 900. While an example manner of forming the example electronic component 200 has been illustrated in FIG. 12, one or more of the steps and/or processes illustrated in FIG. 12 may be combined, divided, re-arranged, omitted, eliminated and/or implemented in any other way. Further still, the example method 1200 of FIG. 12 can include processes and/or steps in addition to, or instead of, those illustrated in FIG. 12 and/or can include more than one of any or all of the illustrated processes and/or steps.

Referring to the example method 1200 of FIG. 12, the method 1200 begins by obtaining a pre-stressed biasing element (block 1202). For example, the pre-stressed leaf spring 224, 922 is pre-stressed (e.g. pre-deflected) to a desired deflection prior to assembly with the electronic component 200, 900. For example, the pre-stressed leaf springs 224 924 can be ordered from a factory or leaf spring manufacturer having the pre-loaded characteristics.

The pre-stressed biasing element is coupled to a thermally conductive structure (block 1204). For example, the pre-stressed leaf spring 224, 922 is coupled to a first surface 306, 910 of the thermally conductive structure 208, 902 (e.g., the vapor chamber) via the first clamping tool 500.

The pre-stressed biasing element is then attached to the thermally conductive structure (block 1206). For example, the pre-stressed leaf spring 224, 922 is then attached to the first surface 306, 910 of the thermally conductive structure 208, 902 via soldering, welding and/or any other attachment technique(s) with the first clamping tool 500 attached to the pre-stressed leaf spring 224, 922 and the thermally conductive structure 208, 902 (as shown for example in FIGS. 5 and 6). For instance, the first clamping tool 500 deflects the pre-stressed leaf spring 224, 922 to be substantially flat to facilitate attachment of the pre-stressed leaf spring 224, 922 and the thermally conductive structure 208, 902.

The first clamping tool is then removed from the pre-stressed biasing element (block 1208). For example, the first clamping tool 500 is removed from the threaded bosses 232, 936 of the pre-stressed leaf spring 224, 922 after the pre-stressed leaf spring 224, 922 is permanently attached to the first surface 306, 910 of the thermally conductive structure 208, 902.

A second clamping tool is attached to the thermally conductive structure (block 1210). For example, the second clamping tool 938 is attached to a second surface 308, 912 of the thermally conductive structure 208, 902 (e.g., as shown for example in FIGS. 11A and 11B). For example, the thermally conductive structure 208 of FIGS. 1-8 can be implemented with the apertures 1002, 1004 of the thermally conductive structure 902 as shown, for example, in FIG. 9. In some examples, the second clamping tool 938 is not used to assemble the electronic component 200 of FIGS. 1-8. In some examples, the apertures 1002, 1004 are formed in the thermally conductive structure 208, 902 (e.g., via a secondary operation or drilling) prior to attachment of the second clamping tool 938.

Next, the thermally conductive structure and the pre-stressed biasing element is coupled to a circuit board (block 1212). For example, the thermally conductive structure 208, 902 and the pre-stressed leaf spring 224, 922 is coupled to the circuit board 202 via the fasteners 234. The second clamping tool 938 provides support to the pre-stressed leaf spring 224, 922 and/or the thermally conductive structure 208, 902 when threading the fasteners 234 with the respective threaded bosses 426, 936 of the pre-stressed leaf spring 224, 922.

After the thermally conductive structure and the pre-stressed biasing element are attached to the circuit board, the second clamping tool is removed from the thermally conductive structure (block 1214). For example, the knobs 960 are rotated to remove the fasteners 956, 958 from the apertures 1002, 1004.

The foregoing examples of the electronic component 200, 900, the thermally conductive structure 208, 902, the pre-stressed leaf spring 224, 922, and/or other components disclosed herein can be employed with an electronic device, a thermal management system, or a thermally conductive structure. Although each example of the electronic component 200, 900, the thermally conductive structure 208, 902, the pre-stressed leaf spring 224, 922 and/or other components disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. Features of one example are not mutually exclusive to the features of another example. Instead, the scope of this disclosure encompasses any combination of any of the features.

Example methods, apparatus, systems, and articles of manufacture and combinations thereof include the following:

Example 1 includes an example electronic component having a circuit board, a processor coupled to the circuit board, and a thermally conductive structure positioned adjacent the processor. The thermally conductive structure is to dissipate heat generated by the processor. The electronic component includes a pre-stressed biasing element coupled to the thermally conductive structure and positioned between the processor and the thermally conductive structure. The pre-stressed biasing element is pre-stressed prior to attachment to the thermally conductive structure and the circuit board.

Example 2 includes the electronic component of example 1, where the thermally conductive structure is a vapor chamber.

Example 3 includes the electronic component of any one of examples 1 and 2, where the pre-stressed biasing element is a leaf spring.

Example 4 includes the electronic component of any one of examples 1-3, where the leaf spring includes a frame and a plurality of arms extending from the frame.

Example 5 includes the electronic component of any one of examples 1-4, where the arms extend from the frame an angle relative to horizontal.

Example 6 includes the electronic component of any one of examples 1-5, where a thickness gap defined between a first side of the circuit board oriented toward the thermally conductive structure and a first surface of the thermally conductive structure oriented toward the first side of the circuit board is approximately between 1.3 millimeters and 1.5 millimeters.

Example 7 includes the electronic component of any one of examples 1-6, where the pre-stressed biasing element is a pre-stressed leaf spring.

Example 8 includes the electronic component of any one of examples 1-7, where each leaf of the pre-stressed leaf spring has a radius of curvature prior to coupling to the thermally conductive structure.

Example 9 includes an example electronic component including a vapor chamber having a first surface and a second surface opposite the first surface and a pre-stressed leaf spring attached to the first surface of the vapor chamber, where the pre-stressed biasing element is pre-stressed prior to attachment to the vapor chamber.

Example 10 includes the electronic component of example 9, where the pre-stressed leaf spring includes a frame and a plurality of arms extending from the frame, each of the arms projecting from the frame at an angle relative to horizontal.

Example 11 includes the electronic component of any one of examples 9-10, where the frame of the pre-stressed leaf spring is permanently attached to the first surface of the vapor chamber.

Example 12 includes an example method including obtaining a pre-stressed biasing element, coupling the pre-stressed biasing element and a first surface of a thermally conductive structure via a first clamping tool, permanently attaching the pre-stressed biasing element and the thermally conductive structure, and removing the first clamping tool from the pre-stressed biasing element.

Example 13 includes the method of example 12, where the coupling of the pre-stressed biasing element and the thermally conductive structure includes attaching the first clamping tool to a first side of the pre-stressed biasing element to substantially flatten a profile of the pre-stressed biasing element.

Example 14 includes the method of any one of examples 12-13, where the permanently attaching the pre-stressed biasing element and the thermally conductive structure includes directly engaging a second side of the pre-stressed biasing element and the first surface of the thermally conductive structure while the first clamping tool is attached to the first side of the pre-stressed biasing element.

Example 15 includes the method of any one of examples 12-14, further including at least one of welding or soldering the pre-stressed biasing element and the first surface of the thermally conductive structure while the first clamping tool is attached to the pre-stressed biasing element.

Example 16 includes the method of any one of examples 12-15, further including coupling a second clamping tool to a second surface of the thermally conductive structure after the pre-stressed biasing element is attached to the first surface of the thermally conductive structure.

Example 17 includes the method of any one of examples 12-16, where the coupling the second clamping tool to the second surface of the thermally conductive surface includes fastening a first fastener of the second clamping tool and a second fastener of the second clamping tool to the thermally conductive structure.

Example 18 includes the method of any one of examples 12-17, further including forming a first aperture and a second aperture through the thermally conductive structure prior to attachment of the second clamping tool.

Example 19 includes the method of any one of examples 12-18, further including coupling the pre-stressed biasing element and the thermally conductive structure with a circuit board while the second clamping tool is attached to the second surface of the thermally conductive structure.

Example 20 includes the method of any one of examples 12-19, further including removing the second clamping tool from the second surface of the thermally conductive structure after attachment of the circuit board and the thermally conductive structure.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. An electronic component comprising:
a circuit board;
a processor coupled to the circuit board; and
a thermally conductive structure positioned adjacent the processor, the thermally conductive structure to dissipate heat generated by the processor; and
a pre-stressed biasing element coupled to the thermally conductive structure and positioned between the processor and the thermally conductive structure, wherein the pre-stressed biasing element is pre-stressed prior to attachment to the thermally conductive structure and the circuit board.

2. The electronic component as defined in claim 1, wherein the thermally conductive structure is a vapor chamber.

3. The electronic component as defined in claim 1, wherein the pre-stressed biasing element is a leaf spring.

4. The electronic component as defined in claim 3, wherein the leaf spring includes a frame and a plurality of arms extending from the frame.

5. The electronic component as defined in claim 4, wherein the arms extend from the frame at an angle relative to horizontal.

6. The electronic component as defined in claim 1, wherein a thickness gap defined between a first side of the circuit board oriented toward the thermally conductive structure and a first surface of the thermally conductive structure oriented toward the first side of the circuit board is approximately between 1.3 millimeters and 1.5 millimeters.

7. The electronic component as defined in claim 1, wherein the pre-stressed biasing element is a pre-stressed leaf spring.

8. The electronic component as defined in claim 7, wherein each leaf of the pre-stressed leaf spring has a radius of curvature prior to coupling to the thermally conductive structure.

9. An electronic device comprising:
a vapor chamber having a first surface and a second surface opposite the first surface; and
a pre-stressed leaf spring attached to the first surface of the vapor chamber, wherein the pre-stressed biasing element is pre-stressed prior to attachment to the vapor chamber.

10. The electronic device as defined in claim 9, wherein the pre-stressed leaf spring includes a frame and a plurality of arms extending from the frame, each of the arms projecting from the frame at an angle relative to horizontal.

11. The electronic device as defined in claim 10, wherein the frame of the pre-stressed leaf spring is permanently attached to the first surface of the vapor chamber.

12. A method for assembling an electronic component, the method comprising:
obtaining a pre-stressed biasing element;
coupling the pre-stressed biasing element and a first surface of a thermally conductive structure via a first clamping tool;
permanently attaching the pre-stressed biasing element and the thermally conductive structure; and
removing the first clamping tool from the pre-stressed biasing element.

13. The method as defined in claim 12, wherein the coupling of the pre-stressed biasing element and the thermally conductive structure includes attaching the first clamping tool to a first side of the pre-stressed biasing element to substantially flatten a profile of the pre-stressed biasing element.

14. The method as defined in claim 13, wherein the permanently attaching the pre-stressed biasing element and the thermally conductive structure includes directly engaging a second side of the pre-stressed biasing element and the first surface of the thermally conductive structure while the first clamping tool is attached to the first side of the pre-stressed biasing element.

15. The method as defined in claim 14, further including at least one of welding or soldering the pre-stressed biasing element and the first surface of the thermally conductive structure while the first clamping tool is attached to the pre-stressed biasing element.

16. The method of claim 12, further including coupling a second clamping tool to a second surface of the thermally conductive structure after the pre-stressed biasing element is attached to the first surface of the thermally conductive structure.

17. The method of claim 16, wherein the coupling the second clamping tool to the second surface of the thermally conductive surface includes fastening a first fastener of the second clamping tool and a second fastener of the second clamping tool to the thermally conductive structure.

18. The method of claim 17, further including forming a first aperture and a second aperture through the thermally conductive structure prior to attachment of the second clamping tool.

19. The method of claim 17, further including coupling the pre-stressed biasing element and the thermally conductive structure with a circuit board while the second clamping tool is attached to the second surface of the thermally conductive structure.

20. The method of claim 19, further including removing the second clamping tool from the second surface of the thermally conductive structure after attachment of the circuit board and the thermally conductive structure.
